(19) United States
(12) Patent Application Publication
(10) Pub. No.: US 2023/0359787 A1
(43) Pub. Date: Nov. 9, 2023

(54) INFORMATION PROCESSING APPARATUS, INFORMATION PROCESSING METHOD, AND RECORDING MEDIUM

(71) Applicant: Panasonic Intellectual Property Management Co., Ltd., Osaka (JP)

(72) Inventors: Yuki IIDA, KANAGAWA KEN (JP); Toshihiro OKUDA, TOKYO TO (JP); Eiichi KURAISHI, KANAGAWA KEN (JP); Kenji YANAGI, KANAGAWA KEN (JP)

(73) Assignee: Panasonic Intellectual Property Management Co., Ltd., Osaka (JP)

(21) Appl. No.: 18/224,773

(22) Filed: Jul. 21, 2023

Related U.S. Application Data
(63) Continuation of application No. PCT/JP2022/001861, filed on Jan. 19, 2022.

(30) Foreign Application Priority Data
Feb. 2, 2021 (JP) 2021-015321

(51) Int. Cl. G06F 30/23; G01R 29/08

(52) U.S. Cl. CPC G06F 30/23; G01R 29/0814

(57) ABSTRACT

An information processing apparatus performs electromagnetic field analysis over a plurality of stages. The information processing apparatus includes a hardware processor connected to a memory. The hardware processor sequentially selects an analysis target and determines one or more analysis regions in the analysis target. The one or more analysis regions are determined on the basis of a parameter relative to mutual influence between structures included in the analysis target. The hardware processor performs electromagnetic field analysis on the one or more analysis regions. The structures include a first structure and a second structure. At least one of the one or more analysis regions includes an entirety of the first structure and part of the second structure.

### CROSS-REFERENCE TO RELATED APPLICATIONS

This application is a continuation of International Application No. PCT/JP2022/001861, filed on Jan. 19, 2022, which claims the benefit of priority of the prior Japanese Patent Application No. 2021-015321, filed on Feb. 2, 2021, the entire contents of which are incorporated herein by reference.

### FIELD

The present disclosure relates generally to an information processing apparatus, an information processing method, and a recording medium.

### BACKGROUND

There is a known drive system that includes an electronic control unit (ECU) and is driven by the ECU. In recent years, since functional integration of ECUs has progressed, the amount of data handled has increased, and the structure has also been more densely arranged. As a result, the amount of generated noise has increased. Therefore, measures for EMC (Electro-Magnetic Compatibility) of ECUs have become more important.

As the measure for EMC, electromagnetic field analysis (simulation) is performed at a design phase of an ECU. However, it is known that, if detailed analysis is performed on the entire analysis space, necessary calculation resources increase, and a long analysis time is required.

To address such disadvantages, a technique has been proposed for performing two-stage analysis. The two-stage analysis is implemented by executing analysis using a fine mesh only on a partial region surrounding a wave source and a small structure, and, after that, executing analysis using a coarse mesh on the entire analysis space including the above-mentioned partial region (see, for example, Japanese patent literature JP 2008-171385 A).

### SUMMARY

An information processing apparatus according to the present disclosure performs electromagnetic field analysis over a plurality of stages. The information processing apparatus includes a hardware processor connected to a memory. The information processing apparatus is configured to sequentially select an analysis target and determine one or more analysis regions in the analysis target. The one or more analysis regions are determined on the basis of a parameter relative to mutual influence between structures included in the analysis target. The information processing apparatus is configured to perform electromagnetic field analysis on the one or more analysis regions. The structures include a first structure and a second structure. At least one of the one or more analysis regions includes an entirety of the first structure and part of the second structure.

### BRIEF DESCRIPTION OF THE DRAWINGS

FIG. 1 is a block diagram illustrating an example of a hardware configuration of an information processing apparatus according to an embodiment;

FIG. 2 is a block diagram illustrating an example of a functional configuration of the information processing apparatus according to the embodiment;

FIG. 3 is a perspective view illustrating an example of entire model data according to the embodiment;

FIG. 4 is a front view illustrating the example of the entire model data according to the embodiment;

FIG. 5 is a perspective view illustrating an example of entire model data according to the embodiment in which a space serving as an analysis target has been selected;

FIG. 6 is a front view illustrating the example of the entire model data according to the embodiment in which the space serving as the analysis target has been selected;

FIG. 7 is a perspective view illustrating an example of entire model data according to the embodiment in which a size of an analysis region has been determined;

FIG. 8 is a front view illustrating the example of the entire model data according to the embodiment in which the size of the analysis region has been determined;

FIG. 9 is a perspective view illustrating an example of entire model data according to the embodiment in which an analysis region has been displayed;

FIG. 10 is a front view illustrating the example of the entire model data according to the embodiment in which the analysis region has been displayed; and

FIG. 11 is a flowchart illustrating an example of processing executed by the information processing apparatus according to the embodiment.

### DETAILED DESCRIPTION

Hereinafter, embodiments of an information processing apparatus, an information processing method, and a recording medium according to the present disclosure will be described with reference to the accompanying drawings. Note that, in the following embodiments, an information processing apparatus that performs electromagnetic field analysis (electromagnetic field simulation) over a plurality of stages at a design phase of an ECU to be mounted on a vehicle will be described.

### Hardware Configuration of Information Processing Apparatus

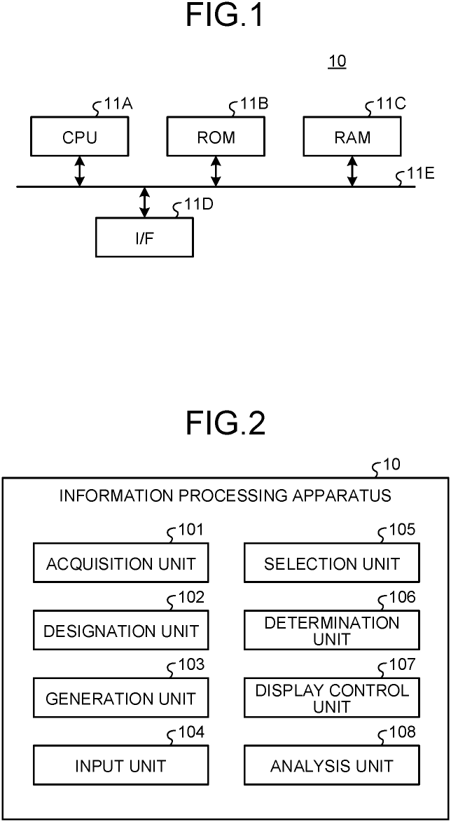

A hardware configuration of an information processing apparatus 10 according to the present embodiment will be described. FIG. 1 is a block diagram illustrating an example of a hardware configuration of the information processing apparatus 10 according to the present embodiment.

The information processing apparatus 10 includes a central processing unit (CPU) 11A, a read only memory (ROM) 11B, a random access memory (RAM) 11C, and an I/F 11D. The components of the information processing apparatus 10 are connected to each other by a bus 11E.

The CPU 11A (an example of the hardware processor) is an arithmetic device that controls the information processing apparatus 10 of the present embodiment. The ROM 11B stores a computer program for implementing various processing by the CPU 11A. The RAM 11C stores data necessary for various processing by the CPU 11A. The I/F 11D is an interface for transmitting and receiving data.

A computer program for executing information processing to be executed by the information processing apparatus 10 of the present embodiment is provided by being installed in the ROM 11B in advance. Note that the computer program to be executed by the information processing apparatus 10 according to the present embodiment may be provided by being recorded in a non-transitory computer-readable recording medium, such as a CD-ROM, a flexible disk (FD), a CD-R, or a digital versatile disc (DVD), as a data file in a format that can be installed or executed in the information processing apparatus 10.

### Functional Configuration of Information Processing Apparatus

Next, a functional configuration of the information processing apparatus 10 according to the present embodiment will be described. FIG. 2 is a block diagram illustrating an example of the functional configuration of the information processing apparatus 10 according to the present embodiment.

The information processing apparatus 10 includes, as functional units, an acquisition unit 101, a designation unit 102, a generation unit 103, an input unit 104, a selection unit 105, a determination unit 106, a display control unit 107, and an analysis unit 108.

The acquisition unit 101 acquires model data (hereinafter, it is also referred to as entire model data) representing an entire analysis target. As the entire model data, the acquisition unit 101 acquires, for example, CAD data representing the entire analysis target.

Specifically, according to a user’s operation input, the acquisition unit 101 acquires, as the entire model data, CAD data, etc., which represents the entire vehicle subject to electromagnetic field analysis and is stored in a storage device such as a hard disc drive (HDD) or a solid state drive (SSD) included in the information processing apparatus 10.

The entire model data may be any data representing the entire analysis target, and is not limited to the CAD data representing the entire vehicle. Moreover, the acquisition unit 101 may acquire the entire model data from an external device such as a server device connected to the information processing apparatus 10 via a communication network.

The designation unit 102 designates the number of analysis stages of the electromagnetic field analysis. The designation unit 102 designates the number of analysis stages of the electromagnetic field analysis in accordance with, for example, the user’s operation input. Note that the designation unit 102 may designate a preset numerical value as the number of analysis stages. Alternatively, the designation unit 102 may automatically designate the number of analysis stages in accordance with the size or the like of the entire model data acquired by the acquisition unit 101.

The generation unit 103 generates a parameter (input parameter) relative to mutual influence between structures included in an analysis target, on the basis of properties of the structures in the analysis target.

Specifically, the generation unit 103 generates, as input parameters for the first stage, theoretical values such as: a frequency of a signal emitted by a member (an example of the structure) included in the analysis target, power consumption of the member, a distance between the member and another member, a material of the other member, and a self-resonant frequency of the other member.

In addition, the generation unit 103 generates an input parameter for the electromagnetic field analysis of the next stage, on the basis of the input parameter for the first stage and an analysis result of the electromagnetic field analysis performed by the analysis unit 108 described later. Note that the generation unit 103 may reuse the input parameter for the first stage as an input parameter for the second and subsequent stages. Alternatively, the generation unit 103 may generate the input parameter for the second and subsequent stages only on the basis of the analysis result of the electromagnetic field analysis by the analysis unit 108.

The input unit 104 inputs the input parameter generated by the generation unit 103 to the entire model data. Specifically, in first-stage electromagnetic field analysis, the input unit 104 inputs the input parameter for the first stage generated by the generation unit 103 to the entire model data acquired by the acquisition unit 101.

In addition, for example, in second-stage electromagnetic field analysis, the input unit 104 inputs, to the entire model data, an input parameter for the second stage generated by the generation unit 103 on the basis of the input parameter for the first stage and the analysis result of the first-stage electromagnetic field analysis.

Note that the input unit 104 may input, to the entire model data, the input parameter for the first stage generated by the generation unit 103 as the input parameter for the second stage. Alternatively, the input unit 104 may input, to the entire model data, the input parameter for the second stage generated by the generation unit 103 only on the basis of the analysis result of the first-stage electromagnetic field analysis.

The selection unit 105 sequentially selects an analysis target. Specifically, the selection unit 105 selects a space serving as the analysis target from the entire model data on the basis of the number of analysis stages designated by the designation unit 102 and the number of stages of analysis to be performed thereafter.

The space serving as the analysis target selected by the selection unit 105 becomes large as the number of analysis stages increases. Then, when the number of analysis stages of the electromagnetic field analysis to be performed reaches the number of analysis stages designated by the designation unit 102, the selection unit 105 selects the entire region of the entire model data as the space serving as the analysis target.

The determination unit 106 determines one or more analysis regions in the analysis target on the basis of the parameter relative to the mutual influence between the structures included in the analysis target selected by the selection unit 105.

Specifically, in the first-stage electromagnetic field analysis, the determination unit 106 determines the size of the analysis region for the space serving as the analysis target in the first-stage electromagnetic field analysis, on the basis of the frequency of the signal emitted by the member serving as a signal source, the power consumption, the distance to the other member, the material of the other member, and the self-resonant frequency of the other member, which have been generated by the generation unit 103 as the input parameters for the first stage.

The determination unit 106 may determine the size of the analysis target on the basis of any one of: the frequency of the signal emitted by the member serving as the signal source, the power consumption, the distance to the other member, the material of the other member, and the self-resonant frequency of the other member, or may determine the size of the analysis target on the basis of information obtained by optionally combining those parameters.

In addition, in the first-stage electromagnetic field analysis, the determination unit 106 determines a boundary condition of the analysis region for the space serving as the analysis target in the first-stage electromagnetic field analysis, on the basis of the distance between the member serving as a signal source and the other member, the material of the other member, and the self-resonant frequency of the other member, which have been generated by the generation unit 103 as the input parameters for the first stage.

Note that the determination unit 106 may determine the boundary condition on the basis of any one of: the distance between the member serving as the signal source and the other member, the material of the other member, and the self-resonant frequency of the other member, or may determine the boundary condition on the basis of information obtained by optionally combining those parameters.

The boundary condition refers to a state of an electric field, a magnetic field, etc. at a boundary portion. Examples of the boundary condition include a free space wall, a perfect matched layer (PML) absorption boundary wall, a periodic boundary wall, an electric wall, and a magnetic wall.

The free space wall indicates that the outside of a boundary portion is a virtual space where no substance exists. The PML absorption boundary wall indicates that a reflected wave at a boundary portion is regarded as zero, and can reduce mismatch in a case where a boundary is provided in a part of the structure. The periodic boundary wall represents a condition to be determined for a boundary surface when analysis is made by modeling only a part of a periodically repeating shape.

The electric wall indicates that the boundary portion is a perfect conductor. When the electromagnetic field analysis is performed, a tangential component of the electric field at the boundary is regarded as 0 in the electric wall. The magnetic wall indicates that the boundary portion is a perfect magnetic conductor. When the electromagnetic field analysis is performed, a tangential component of the magnetic field at the boundary is regarded as 0 in the magnetic wall.

In the first-stage electromagnetic field analysis, the determination unit 106 determines the mesh condition of the analysis region for the space serving as the analysis target in the first-stage electromagnetic field analysis, on the basis of the frequency of the signal emitted by the member serving as the signal source, the power consumption, the distance to the other member, the material of the other member, and the self-resonant frequency of the other member, which have been generated by the generation unit 103 as the input parameters for the first stage.

Note that the determination unit 106 may determine the mesh condition on the basis of any one of: the frequency of the signal emitted by the member serving as the signal source, the power consumption, the distance to the other member, the material of the other member, and the self-resonant frequency of the other member, or may determine the mesh condition on the basis of information obtained by optionally combining those parameters.

The mesh condition refers to fineness of a mesh used for the electromagnetic field analysis of the analysis region. Note that the condition determined by the determination unit 106 is not limited to the size of the analysis region, the boundary condition, and the mesh condition. Another condition may also be determined as long as the condition is related to the analysis region.

In addition, for example, in the second-stage electromagnetic field analysis, the determination unit 106 determines the size of the analysis region, the boundary condition, and the mesh condition for the space serving as the analysis target in the second-stage electromagnetic field analysis on the basis of the input parameter for the second stage generated by the generation unit 103, on the basis of the input parameter for the first stage and the analysis result of the first-stage electromagnetic field analysis.

Note that the determination unit 106 may determine the size of the analysis region, the boundary condition, and the mesh condition for the space serving as the analysis target in the second-stage electromagnetic field analysis, on the basis of the input parameter for the first stage generated by the generation unit 103. Alternatively, the determination unit 106 may determine the size of the analysis region, the boundary condition, and the mesh condition on the basis of the input parameter for the second stage generated by the generation unit 103 only on the basis of the analysis result of the first-stage electromagnetic field analysis.

The display control unit 107 performs control to display, on a display device, an indication relative to processing of the information processing apparatus 10. As the display device, a liquid crystal display (LCD), a Cathode Ray Tube (CRT) display, an organic EL (Organic Electro Luminescence Display, OELD) display, a plasma display, etc. can be used.

For example, the display control unit 107 controls the display device to display the entire model data acquired by the acquisition unit 101. In addition, for example, the display control unit 107 controls the display device to display the size of the analysis region and the boundary condition determined by the determination unit 106.

Note that the display control unit 107 may display only the size of the analysis region determined by the determination unit 106 on the display device. Alternatively, the display control unit 107 may display the size of the analysis region and mesh condition on the display device. Alternatively, the display control unit 107 may display the size of the analysis region, boundary condition, and mesh condition on the display device.

In addition, for example, the display control unit 107 performs control to display, on the display device, the analysis result of the electromagnetic field analysis performed by the analysis unit 108. The displaying is one form of output, and the display control unit 107 is an example of an output control unit. The information processing apparatus 10 may transmit (output) the analysis result of the electromagnetic field analysis to a terminal device such as a notebook PC or a tablet PC, for example, instead of displaying the analysis result of the electromagnetic field analysis on the display device.

In addition, the display control unit 107 performs control to display the analysis result on the display device every time a stage of the analysis is completed. This configuration allows the user to check the analysis result in each stage, and thus grasp the validity of the analysis for each stage.

In addition, the information processing apparatus 10 may be configured to be able to stop analysis at the next and subsequent stages when the analysis result at the current stage is not appropriate. For example, the display control unit 107 displays a message asking whether or not to stop analysis until a predetermined time elapses after the analysis result is displayed, so as to enable the user to input an instruction indicating a stoppage of analysis. With this configuration, the user can perform the electromagnetic field analysis efficiently without waste.

The analysis unit 108 performs the electromagnetic field analysis on the analysis region. In addition, the analysis unit 108 performs the electromagnetic field analysis for the number of stages designated by the designation unit 102. Note that a known method can be used as the electromagnetic field analysis method by the analysis unit 108. Examples of the electromagnetic field analysis method include a moment method, a finite element method, and a finite difference time domain (FDTD) method.

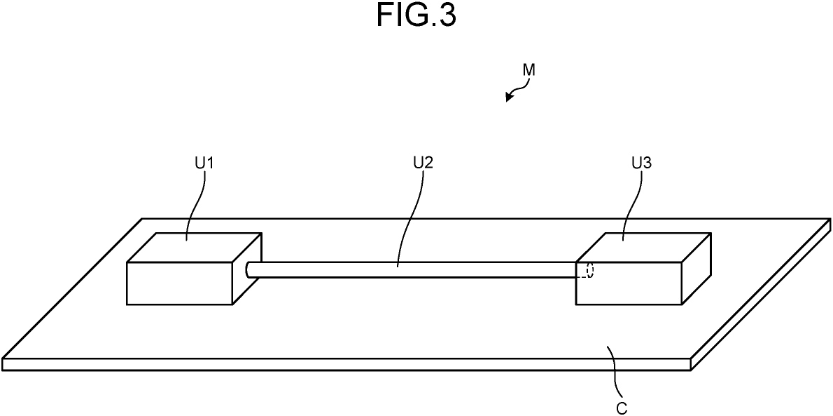

The designation of the number of analysis stages, the selection of the analysis target, and the determination of the analysis region will be described in detail with reference to FIGS. 3 to 10.

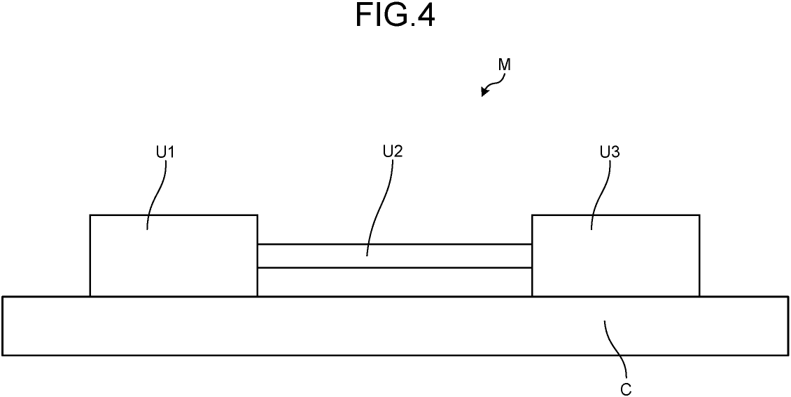

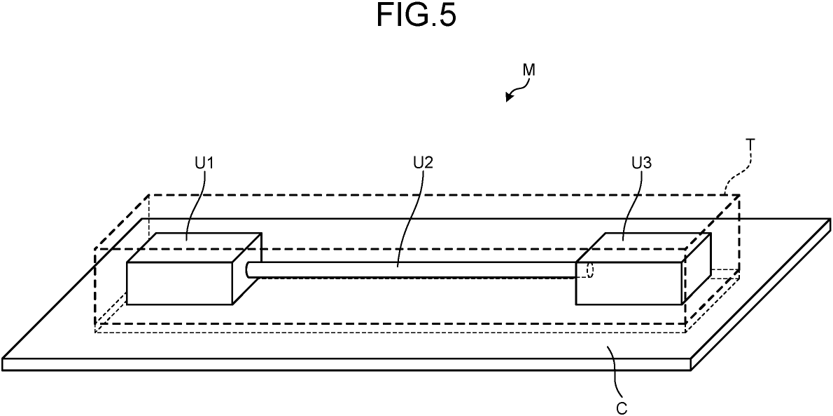

First, the acquisition unit 101 acquires the entire model data in accordance with the user’s operation input (designation). The display control unit 107 controls the display device to display the entire model data acquired by the acquisition unit 101. FIG. 3 is a perspective view illustrating an example of the entire model data. FIG. 4 is a front view illustrating the example of the entire model data.

In FIG. 3 and FIG. 4, vehicle model data M (an example of the entire model data) is constituted by a unit A model U1, a harness model U2, a unit B model U3, and a vehicle body model C. Since the entire model data is displayed on the display device in this manner, the user can check whether or not the entire model data designated by himself/herself is correct.

Next, the user performs input for designating the number of analysis stages. For example, when the user inputs “2” as the number of analysis stages, the designation unit 102 designates “2” as the number of analysis stages.

The generation unit 103 generates, as the input parameters, for example, theoretical values of: power consumption of the unit A, a frequency of a signal emitted by the unit A, a distance between the unit A and the harness, a material of the harness, a self-resonant frequency of the harness, power consumption of the unit B, a frequency of a signal emitted by the unit B, and a distance between the unit B and the harness.

The input unit 104 inputs, to the vehicle model data M, the input parameter generated by the generation unit 103 such as the frequency of the signal emitted by the unit A.

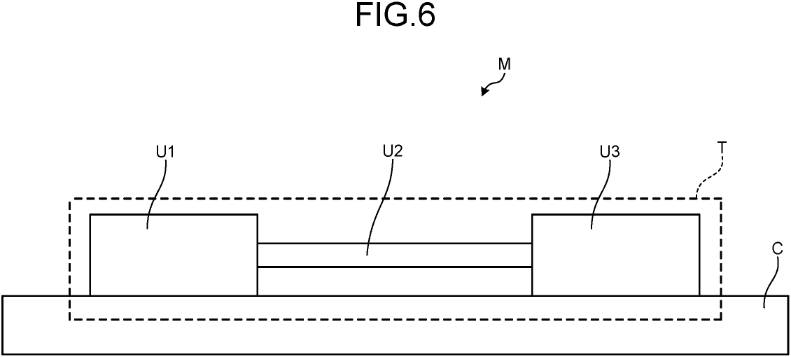

Next, the selection unit 105 selects the space serving as the analysis target from the vehicle model data M, in accordance with the number of analysis stages designated by the designation unit 102. FIG. 5 is a perspective view illustrating an example of the entire model data in which the space serving as the analysis target has been selected. In addition, FIG. 6 is a front view illustrating an example of the entire model data in which the space serving as the analysis target has been selected.

In this example, the designation unit 102 designates “2” as the number of analysis stages. Therefore, the selection unit 105 selects, from the vehicle model data M, an analysis space T serving as the analysis target in the first stage such that a space serving as the analysis target in the second stage becomes the entire region of the vehicle model data M.

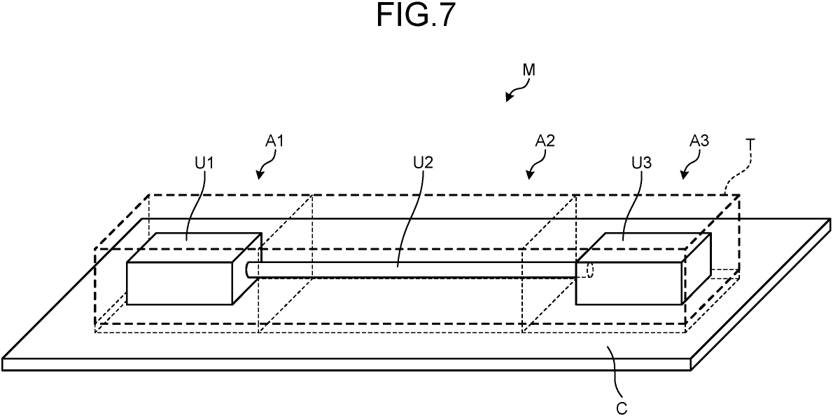

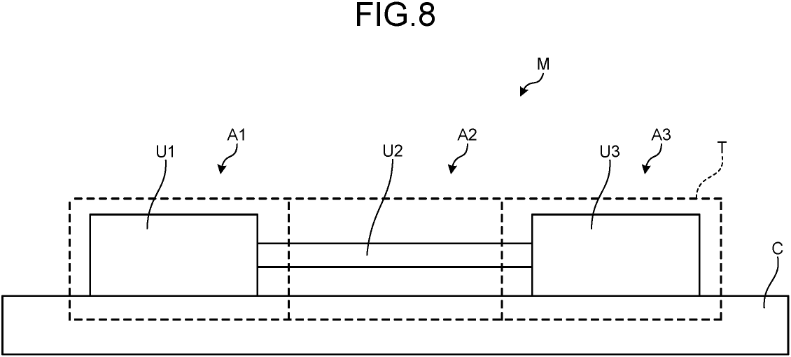

The determination unit 106 determines the size of the analysis region in accordance with, for example, the frequency of the signal emitted by the unit A. FIG. 7 is a perspective view illustrating an example of the entire model data in which the size of the analysis region has been determined. In addition, FIG. 8 is a front view illustrating an example of the entire model data in which the size of the analysis region has been determined.

In this example, the determination unit 106 determines three analysis regions of a first region A1, a second region A2, and a third region A3 for the analysis space T, in accordance with the frequency or the like of the signal emitted by the unit A. At this time, the determination unit 106 determines the respective sizes of the first region A1, the second region A2, and the third region A3.

Note that, the lower the frequency of the signal emitted by the unit A is, the larger the size of the first region A1 becomes. This is because the lower the frequency, the smaller the attenuation amount and the larger the range of influence on the surroundings. Similarly, the higher the power consumption of the unit A is, the larger the size of the first region A1 becomes. This is because the higher the power consumption, the larger the range of influence on the surroundings.

Similarly, the nearer the distance between the unit A and the other member is, the larger the size of the first region A1 becomes, in principle. This is because the nearer the distance to the other member, the larger the range of influence of the unit A on the other member.

However, in a case where the other member is non-metal, the influence on the other member is small, so that it is not necessary to increase the size of the analysis region. Therefore, it is preferable to use the distance to the other member together with the material of the other member as an element used to determine the size of the analysis region.

In addition, when the self-resonant frequency of the other member present in the vicinity of the unit A matches the frequency subject to the analysis, the size of the first region A1 becomes large. This is because when the frequency subject to the analysis matches the self-resonant frequency of the other member, signals emitted from the other member and the unit A affect each other.

Moreover, the determination unit 106 determines the boundary condition in accordance with, for example, the distance between the unit A and the other member, the material of the other member, etc. Specifically, for the first region A1, the determination unit 106 determines the boundary condition (free space wall, electric wall, magnetic wall, PML absorption boundary wall, periodic boundary wall, etc.) for each boundary portion of the first region A1 in accordance with the structure (or state) outside the first region A1. In addition, the determination unit 106 also performs similar processing for the second region A2 and the third region A3.

Note that, in a case where, for example, the entire unit A is included in the first region A1 and the structure of the other member is not included, the determination unit 106 determines the boundary condition of each surface of the first region A1 as a free space wall. In addition, in a case where the structure of the other member than the unit A is included in the first region A1 (for example, a harness), the determination unit 106 determines the boundary condition of the surface including the structure of the other member as a PML absorption boundary wall. Alternatively, the determination unit 106 may determine the boundary condition as an electric wall or a magnetic wall depending on the material of the other member.

In addition, the determination unit 106 determines the mesh condition (mesh fineness, etc.) in accordance with, for example, the frequency of the signal emitted by the unit A. Specifically, the determination unit 106 determines the mesh fineness for the analysis of the first region A1 in accordance with the frequency or the like of the signal emitted by the unit A.

The higher the frequency of the signal emitted by the unit A is, the finer the mesh for the analysis of the first region A1 becomes. This is because the higher the frequency, the more complicated the phenomenon that occurs, which requires more detailed analysis. Similarly, the higher the power consumption of the unit A is, the finer the mesh for the analysis of the first region A1 becomes. This is because the higher the power consumption, the larger the influence on the analysis result, which requires the phenomenon to be accurately reproduced.

Similarly, the shorter the distance between the unit A and the other member is, the finer the mesh for the analysis of the first region A1 becomes, in principle. This is because the nearer the distance to the other member, the more complicated the phenomenon that occurs, which requires more detailed analysis.

However, in a case where the other member is non-metal, the influence on the other member is small, so that it is possible to suppress the miniaturization of the mesh. Therefore, it is preferable to use the distance to the other member together with the material of the other member as an element used to determine the mesh condition.

In addition, in a case where the self-resonant frequency of the other member present in the vicinity of the unit A matches the frequency subject to the analysis, the mesh for the analysis of the first region A1 becomes fine. This is because when the frequency subject to the analysis matches the self-resonant frequency of the other member, signals emitted from the other member and the unit A easily affect each other, which requires more detailed analysis.

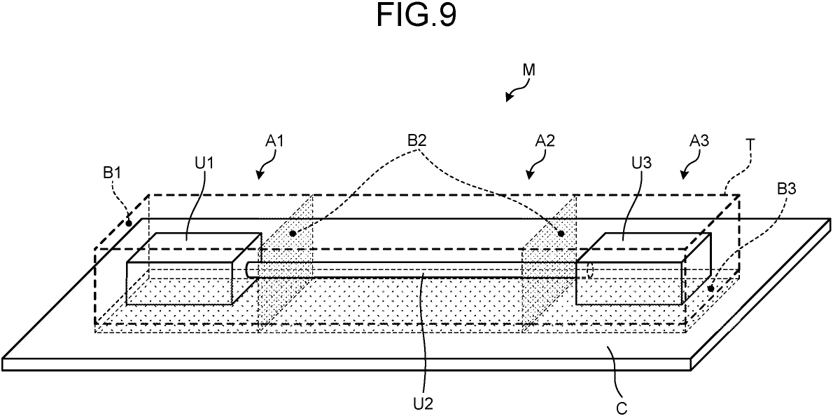

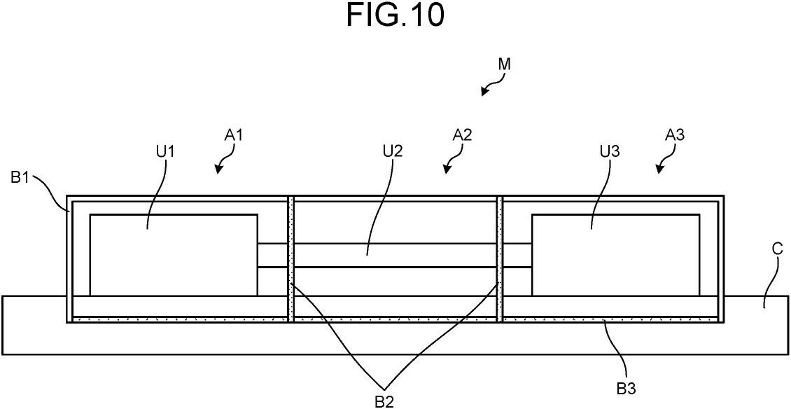

The display control unit 107 controls the display device to display the analysis region determined by the determination unit 106. FIG. 9 is a perspective view illustrating an example of the entire model data in which the analysis region has been displayed. FIG. 10 is a front view illustrating an example of the entire model data in which the analysis region has been displayed.

In this example, the determination unit 106 determines, as a free space wall B1, the boundary condition of the front surface, the back surface, the top surface, and the left side surface of the first region A1. Additionally, the determination unit 106 determines the boundary condition of the right side surface as a PML absorption boundary wall B2, and determines the boundary condition of the bottom surface as an electric wall B3.

Moreover, the determination unit 106 determines, as a free space wall B1, the boundary condition of the front surface, the back surface, and the top surface of the second region A2. Additionally, the determination unit 106 determines the boundary condition of the right side surface as a PML absorption boundary wall B2, and determines the boundary condition of the bottom surface as an electric wall B3. Moreover, the determination unit 106 determines, as the free space wall B1, the boundary condition of the front surface, the back surface, the top surface, and the right side surface of the third region A3, and determines the boundary condition of the bottom surface as the electric wall B3.

The display control unit 107 controls the display device to display the respective sizes of the first region A1, the second region A2, and the third region A3 determined by the determination unit 106. In addition, the display control unit 107 also controls the display device to display the boundary condition determined by the determination unit 106 together with the sizes of the analysis regions. Displaying the analysis regions in this manner allows the user to verify whether or not the automatically performed analysis region determination is appropriate.

Then, if the determination of the analysis region is not appropriate, the user can perform input for correcting each. With this configuration, the information processing apparatus 10 according to the present embodiment can efficiently perform the analysis as compared with a case where the user manually performs all the actions such as determining the size of the analysis region and determining the boundary condition.

In addition, the analysis region is displayed on the display device in an easy-to-understand manner by the display control unit 107, so that the user can easily determine the validity of the determined size of the analysis region, the boundary condition, etc. Moreover, in a case where the user determines that the automatically determined analysis region is not appropriate, the size of the analysis region, the boundary condition, etc. can be corrected. Therefore, the information processing apparatus 10 according to the present embodiment can perform the analysis without deteriorating the accuracy.

### Processing of Information Processing Apparatus

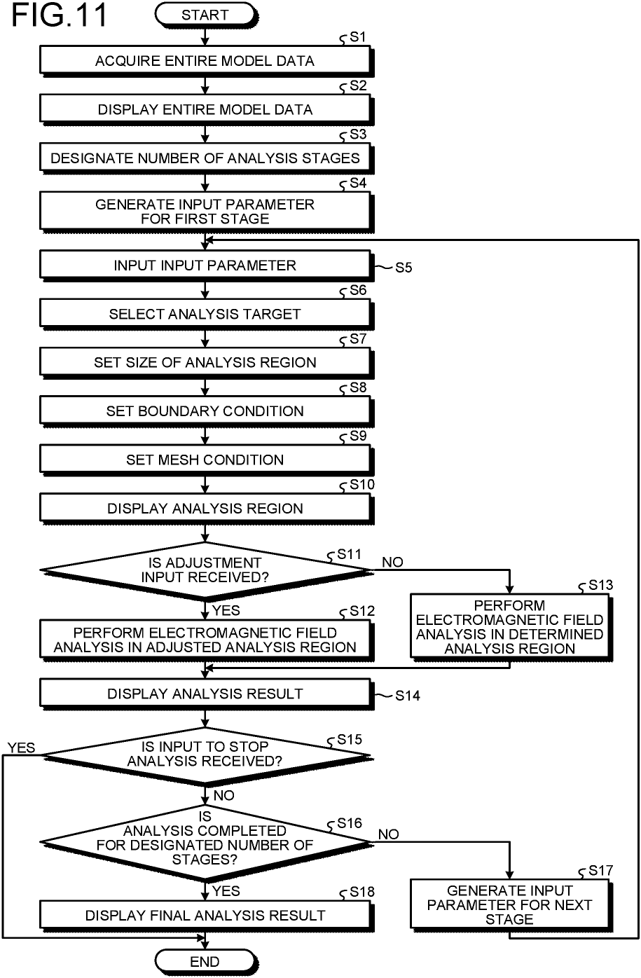

Next, processing executed by the information processing apparatus 10 will be described. FIG. 11 is a flowchart illustrating an example of the processing executed by the information processing apparatus 10.

First, the acquisition unit 101 acquires the entire model data in accordance with the user’s designation (Step S1).

The display control unit 107 controls the display device to display the entire model data acquired by the acquisition unit 101 (Step S2).

Next, the designation unit 102 designates the number of analysis stages of the electromagnetic field analysis in accordance with the user’s input (Step S3). Note that, in Step S3, the designation unit 102 in this example designates the number of stages of the electromagnetic field analysis in accordance with the user’s input, but the designation unit 102 may automatically designate the number of analysis stages in accordance with the size of the entire model data acquired by the acquisition unit 101 or the like.

The generation unit 103 generates, as the input parameters for the first stage, the frequency of the signal emitted by the member included in the entire model data, the power consumption of the member, the distance between the member and the other member, the material of the other member, and the self-resonant frequency of the other member (Step S4).

The input unit 104 inputs the input parameter generated by the generation unit 103 to the entire model data (Step S5).

The selection unit 105 selects, from the entire model data, the space serving as the analysis target in the first-stage electromagnetic field analysis in accordance with the number of analysis stages designated by the designation unit 102 (Step S6). After the first-stage electromagnetic field analysis, the selection unit 105 selects, from the entire model data, the space serving as the analysis target in the electromagnetic field analysis in accordance with the number of analysis stages designated by the designation unit 102 and the stage order of the electromagnetic field analysis to be performed thereafter.

The determination unit 106 determines the size of the analysis region for the space serving as the analysis target selected by the selection unit 105 on the basis of the distance between the member included in the entire model data and the other member, the material of the other member, and the self-resonant frequency of the other member, which have been input by the input unit 104 (Step S7).

The determination unit 106 determines the boundary condition of the analysis region on the basis of the frequency of the signal emitted by the member included in the entire model data, the power consumption of the member, the distance between the member and the other member, the material of the other member, and the self-resonant frequency of the other member, which have been input by the input unit 104 (Step S8).

The determination unit 106 determines the mesh condition of the analysis region on the basis of the frequency of the signal emitted by the member included in the entire model data, the power consumption of the member, the distance between the member and the other member, the size of the other member, the material of the other member, and the self-resonant frequency of the other member, which have been input by the input unit 104 (Step S9).

The display control unit 107 controls the display device to display the analysis region determined by the determination unit 106 (size of the analysis region, boundary condition, and mesh condition) (Step S10).

The analysis unit 108 receives an adjustment input or a confirmation input of the size of the analysis region, the boundary condition, and the mesh condition from the user (Step S11). When the adjustment input of the size of the analysis region, the boundary condition, and the mesh condition is received from the user (Step S11: Yes), the analysis unit 108 performs the electromagnetic field analysis using the size of the analysis region, the boundary condition, and the mesh condition, which have been adjusted by the user (Step S12).

On the other hand, then the confirmation input of the size of the analysis region, the boundary condition, and the mesh condition is received from the user (Step S11: No), the analysis unit 108 performs the electromagnetic field analysis using the size of the analysis region, the boundary condition, and the mesh condition, which have been determined by the determination unit 106 (Step S13).

The display control unit 107 controls the display device to display the analysis result of the electromagnetic field analysis performed by the analysis unit 108 (Step S14). Then, the analysis unit 108 checks whether or not input of a stoppage of the analysis is received from the user before a predetermined time elapses (Step S15). When the input of a stoppage of the analysis is received (Step S15: Yes), the analysis unit 108 stops the electromagnetic field analysis and ends the processing.

On the other hand, when the input of a stoppage of the analysis is not received (Step S15: No), the analysis unit 108 checks whether or not the electromagnetic field analysis has been completed for the number of stages designated by the designation unit 102 (Step S16). When the electromagnetic field analysis has not been completed for the designated number of stages (Step S16: No), the generation unit 103 generates the input parameter for the next-step electromagnetic field analysis on the basis of the input parameter for the first stage and the analysis result of the electromagnetic field analysis performed by the analysis unit 108, and proceeds to the processing of Step S5 (Step S17).

On the other hand, when the electromagnetic field analysis has been completed for the designated number of stages (Step S16: Yes), the display control unit 107 performs control for displaying the final analysis result of the electromagnetic field analysis performed by the analysis unit 108 on the display device, and ends this processing (Step S18).

### Technical Advantages of Information Processing Apparatus

Technical advantages of the information processing apparatus 10 according to the present embodiment will be described. The information processing apparatus 10 according to the present embodiment is an information processing apparatus that performs electromagnetic field analysis over a plurality of stages. The information processing apparatus 10 includes the selection unit 105, the determination unit 106, and the analysis unit 108. The selection unit 105 sequentially serves to select the analysis target. The determination unit 106 serves to determine one or more analysis regions in the analysis target on the basis of the parameter relative to mutual influence between the structures included in the analysis target. The analysis unit 108 serves to perform the electromagnetic field analysis on the analysis regions determined by the determination unit 106.

The determination unit 106 determines the size of the analysis region in accordance with the parameter relative to the mutual influence between the structures included in the analysis target, so that it is possible to determine the size of the analysis region in consideration of the mutual influence between the analysis regions. Therefore, the information processing apparatus 10 according to the present embodiment can perform highly accurate multi-stage electromagnetic field analysis as compared with a case where the size of the analysis region is the same as the size of the member.

In addition, the parameter includes at least one of: the frequency of the signal emitted by the structure, the power consumption of the structure, the distance between the structure and the other structure, the material of the structure, and the self-resonant frequency of the structure.

Changes in the frequency and the like of the signal emitted by the member can become elements that affect the electric field and/or the magnetic field around the member. Therefore, these can be said to be elements indicating the strength of the mutual influence between the structures included in the analysis target. That is, by using at least one of these as a determination parameter for determining the size of the analysis region, the determination unit 106 can determine the size of the analysis region in consideration of the mutual influence between the analysis regions.

Similarly, by using at least one of these as a determination parameter for determining the boundary condition of the analysis region, the determination unit 106 can determine the boundary condition for performing highly accurate electromagnetic field analysis.

In addition, similarly, by using at least one of these as a determination parameter for determining the mesh condition of the analysis region, the determination unit 106 can determine the mesh condition for performing highly accurate electromagnetic field analysis.

In addition, the information processing apparatus 10 includes the display control unit 107 that displays the analysis result of the electromagnetic field analysis performed by the analysis unit 108. With this configuration, the information processing apparatus 10 can notify the user of the analysis result of the electromagnetic field analysis by the analysis unit 108.

In addition, the display control unit 107 performs control for displaying the size of the analysis region determined by the determination unit 106 on the display device. With this configuration, the user can visually grasp the size of the analysis region determined by the determination unit 106. Therefore, it is considered that the user can intuitively determine the validity of the automatically determined size of the analysis region.

In addition, the display control unit 107 performs control for displaying the boundary condition determined by the determination unit 106 on the display device, together with the size of the analysis region. With this configuration, the user can visually grasp the boundary condition determined by the determination unit 106. Therefore, it is considered that the user can intuitively determine the validity of the automatically determined boundary condition.

In addition, the display control unit 107 performs control for displaying the mesh condition determined by the determination unit 106 on the display device, together with the size of the analysis region. With this configuration, the user can visually grasp the mesh condition determined by the determination unit 106. Therefore, it is considered that the user can intuitively determine the validity of the automatically determined mesh condition.

Note that the computer program for executing the information processing in the above-described embodiment has a module configuration including the above-described functional units, and as actual hardware, for example, the CPU (processor circuit) reads and executes the information processing program from the ROM or the HDD, whereby the above-described functional units are loaded onto the RAM (main storage), and the above-described functional units are generated on the RAM (main storage).

Note that part of or all the above-described functional units can also be implemented using dedicated hardware such as an application specific integrated circuit (ASIC) or a field-programmable gate array (FPGA).

The above-described embodiments can be implemented with appropriate modification by changing part of the configuration or function included in the information processing apparatus 10. Hereinafter, some modifications according to the above-described embodiments will be described as other embodiments. In the following description, points different from the above-described embodiments will be mainly described, and detailed description of points common to the contents already described will be omitted. In addition, the modifications described below may be implemented individually, or may be implemented in appropriate combination.

### First Modification

In the embodiment described above, the frequency of the signal emitted by the member and the power consumption of the member are included in part of the input parameter. However, instead of the frequency of the signal emitted by the member and the power consumption of the member, a signal waveform of the signal emitted by the member may be included in the input parameter. In this case, the frequency of the signal emitted by the member and the power consumption of the member are calculated from the signal waveform.

### Second Modification

In the embodiment described above, the frequency of the signal emitted by the member, the power consumption of the member, the distance between the member and the other member, the material of the other member, and the self-resonant frequency of the other member are used as the input parameters. However, the information included in the input parameter is not limited thereto. For example, a ground condition of the signal source may be used as the input parameter.

In this case, the determination unit 106 determines the size of the analysis region in accordance with the size that has been secured as the ground of the signal source. More specifically, the determination unit 106 determines the size of the analysis region such that the smaller the size of the ground of the signal source is, the larger the size of the analysis region. This is because a smaller size of the ground of the signal source causes the radiation noise to increase, resulting in a larger influence on the surroundings.

In addition, for the similar reason, the determination unit 106 determines the mesh condition such that the smaller the size of the ground of the signal source is, the finer the mesh to be used for the analysis becomes. The information processing apparatus 10 of the present modification can perform highly accurate electromagnetic field analysis by determining the analysis region in accordance with the ground condition of the signal source.

While certain embodiments have been described, these embodiments have been presented by way of example, and are not intended to limit the scope of the inventions. Indeed, the novel methods and systems described herein may be embodied in a variety of other forms; moreover, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An information processing apparatus performing electromagnetic field analysis over a plurality of stages, the information processing apparatus comprising
a hardware processor connected to a memory and configured to:
sequentially select an analysis target;
determine one or more analysis regions in the analysis target, the one or more analysis regions being determined on the basis of a parameter relative to mutual influence between structures included in the analysis target; and
perform electromagnetic field analysis on the one or more analysis regions, wherein
the structures include a first structure and a second structure, and
at least one of the one or more analysis regions includes an entirety of the first structure and part of the second structure.

2. The information processing apparatus according to claim 1, wherein the parameter includes at least one of: frequencies of signals emitted by the structures, power consumption of the structure, a distance between the first structure and the second structure, a material of the structure, and a self-resonant frequency of the structure.

3. The information processing apparatus according to claim 2, wherein the parameter further includes a ground condition indicating a size and a shape of a ground of one of the structures serving as a signal source.

4. The information processing apparatus according to claim 1, wherein the hardware processor is configured to determine, on the basis of the parameter, respective sizes of the analysis regions, boundary conditions indicating states of respective boundary portions of the analysis regions, and mesh conditions including respective mesh fineness of the analysis regions.

5. The information processing apparatus according to claim 1, wherein the hardware processor is configured to determine, on the basis of the parameter, respective sizes of the analysis regions, boundary conditions indicating states of respective boundary portions of the analysis regions, and mesh conditions including respective mesh fineness of the analysis regions.

6. The information processing apparatus according to claim 3, wherein the hardware processor is configured to determine, on the basis of the parameter, respective sizes of the analysis regions, boundary conditions indicating states of respective boundary portions of the analysis regions, and mesh conditions including respective mesh fineness of the analysis regions.

7. The information processing apparatus according to claim 4, wherein the hardware processor is further configured to output an analysis result of the electromagnetic field analysis.

8. The information processing apparatus according to claim 7, wherein the hardware processor is configured to perform control a display device to display information indicating the respective sizes of the analysis regions.

9. The information processing apparatus according to claim 8, wherein the hardware processor is configured to perform control the display device to display information indicating the boundary conditions together with the information indicating the respective sizes of the analysis regions.

10. The information processing apparatus according to claim 8, wherein the hardware processor is configured to perform control the display device to display information indicating the mesh conditions together with the information indicating the respective sizes of the analysis regions.

11. The information processing apparatus according to claim 9, wherein the hardware processor is configured to perform control the display device to display information indicating the mesh conditions together with the information indicating the respective sizes of the analysis regions.

12. An information processing method implemented by an information processing apparatus performing electromagnetic field analysis over a plurality of stages, the information processing method comprising:
sequentially selecting an analysis target;
determining one or more analysis regions in the analysis target, the one or more analysis regions being determined on the basis of a parameter relative to mutual influence between structures included in the analysis target; and
performing electromagnetic field analysis on the one or more analysis regions, wherein
the structures include a first structure and a second structure, and
at least one of the one or more analysis regions includes an entirety of the first structure and part of the second structure.

13. A non-transitory computer-readable recording medium on which programmed instructions are recorded, the instructions causing a computer to execute processing, the computer being included in an information processing apparatus performing electromagnetic field analysis over a plurality of stages, the processing executed by the computer comprising:
sequentially selecting an analysis target;
determining one or more analysis regions in the analysis target, the one or more analysis regions being determined on the basis of a parameter relative to mutual influence between structures included in the analysis target; and
performing electromagnetic field analysis on the one or more analysis regions, wherein
the structures include a first structure and a second structure, and
at least one of the one or more analysis regions includes an entirety of the first structure and part of the second structure.
